(19) United States
(12) Patent Application Publication
(10) Pub. No.: US 2026/0074160 A1
(43) Pub. Date: Mar. 12, 2026

(54) SUBSTRATE PROCESSING DEVICE AND INNER CHAMBER ASSEMBLY

(71) Applicant: Tokyo Electron Limited, Tokyo (JP)

(72) Inventors: Koei ITO, Miyagi (JP); Dai KITAGAWA, Miyagi (JP); Taisei SEGUCHI, Miyagi (JP)

(73) Assignee: Tokyo Electron Limited, Tokyo (JP)

(21) Appl. No.: 19/389,094

(22) Filed: Nov. 14, 2025

Related U.S. Application Data
(63) Continuation of application No. PCT/JP2024/017676, filed on May 13, 2024.

(30) Foreign Application Priority Data
May 26, 2023 (JP) 2023-087117

(51) Int. Cl. H01J 37/32

(52) U.S. Cl. CPC H01J 37/32605; H01J 37/3244; H01J 37/32541; H01J 37/3255; H01J 37/32568; H01J 37/32577; H01J 37/32899

(57) ABSTRACT

A substrate processing device includes a first member including a ceiling and a second member including a side wall and supporting the first member. The second member is electrically connected to a ground member that is grounded and surrounds a substrate support. The first member and the second member are individual members and separable from each other.

### CROSS-REFERENCE TO RELATED APPLICATIONS

This application is a Continuation of PCT International Application No. PCT/JP2024/017676, filed on May 13, 2024, which claims priority under 35 U.S.C. § 119 (a) to Japanese Patent Application No. JP 2023-087117, filed in Japan on May 26, 2023, all of which are hereby expressly incorporated by reference into the present application.

### FIELD

Exemplary embodiments of the disclosure relate to a substrate processing device and an inner chamber assembly.

### BACKGROUND

A substrate processing device/plasma processing device performs plasma processing of substrates. The plasma processing device includes a chamber and a substrate support. The substrate support supports a substrate in the chamber. The substrate is processed with a chemical species in plasma generated from a process gas in the chamber. Patent Literature 1 below describes such a plasma processing device.

### CITATION LIST

### Patent Literature

Patent Literature 1: Japanese Unexamined Patent Application Publication No. 2019-197849

### BRIEF SUMMARY

One or more aspects of the disclosure are directed to a technique for reducing the cost for replacing a chamber defining a processing space.

A substrate processing device according to one exemplary embodiment includes a first chamber in which a substrate support to receive a substrate is located, and a second chamber located in the first chamber. The second chamber includes a first member including a ceiling located above the substrate support, and a second member including a side wall and supporting the first member. The second member is electrically connected to a ground member that is grounded and surrounds the substrate support. The first member and the second member are individual members and separable from each other.

### Advantageous Effects

The technique according to one or more embodiments reduces the cost for replacing the chamber defining a processing space.

### BRIEF DESCRIPTION OF THE DRAWINGS

FIG. 1 is a diagram of a substrate processing system according to one or more embodiments.

FIG. 2 is a schematic diagram of a transfer module in the substrate processing system according to the exemplary embodiment.

FIG. 3 is a schematic diagram of a substrate processing device according to one or more embodiments.

FIG. 4 is a partially enlarged cross-sectional view of the substrate processing device according to one or more embodiments.

FIG. 5 is a schematic diagram of a second chamber (inner chamber assembly) in a substrate processing device according to one or more embodiments.

FIG. 6 is a schematic diagram of a second chamber in a substrate processing device according to still one or more embodiments.

FIG. 7 is a schematic diagram of a second chamber in a substrate processing device according to still one or more embodiments.

FIG. 8 is a schematic diagram of a second chamber in a substrate processing device according to still one or more embodiments.

FIG. 9 is a cross-sectional view taken along line IX-IX in FIG. 8.

FIG. 10 is a schematic diagram of a second chamber in a substrate processing device according to still one or more embodiments.

FIG. 11 is a schematic diagram of a substrate processing device according to one or more embodiments.

FIG. 12 is a schematic diagram of a second chamber in a substrate processing device according to still one or more embodiments.

### DETAILED DESCRIPTION

Exemplary embodiments will now be described.

A substrate processing device according to one or more embodiments includes a first chamber in which a substrate support to receive a substrate is located, and a second chamber located in the first chamber. The second chamber includes a first member including a ceiling located above the substrate support, and a second member including a side wall and supporting the first member. The second member is electrically connected to a ground member that is grounded and surrounds the substrate support. The first member and the second member are individual members and separable from each other.

In the above substrate processing device, a plasma processing space is defined by the substrate support, the first member including the ceiling located above the substrate support, and the second member including the side wall. Radio-frequency (RF) waves to generate plasma return through the second member connected to the ground member as a return path. In the substrate processing device, the first member located above the substrate support on which the substrate is placed is likely to wear. With the structure including the first member and the second member that are individual members, the first member that has worn can be simply replaced for maintenance. This reduces the cost for replacing the chamber defining the processing space.

In one or more embodiments, the first member and the second member may be formed from different materials. In this structure, a material may be selected for each member based on, for example, intended functions.

In one or more embodiments, the first member may be formed from a Si-containing material. The Si-containing material may contain silicon as a constituent element. For example, the first member may be formed from one of Si, SiC, SiO₂, or Si₃N₄. The second member may be formed from a metal material. In this structure, the first member, which is likely to wear, is formed from a low contamination material, and the second member, which serves as the return path for RF waves, is formed from a metal material with low electrical resistance.

In one or more embodiments, the first member may have a gas hole. This structure facilitates supply of a gas to the processing space.

In one or more embodiments, the first member may include a protruding edge engaged with the second member. This structure prevents the first member from slipping off the second member.

In one or more embodiments, the substrate processing device may further include a third member located along an inner surface of the side wall in the second member. This structure may reduce wear of the inner surface of the second member.

In one or more embodiments, the third member may be annular. This structure may reduce wear of the inner surface of the second member.

In one or more embodiments, the third member may include a plurality of parts separable in a circumferential direction. This structure includes the third member separable into smaller parts and thus facilitates placement of the third member along the inner surface of the second member.

In one or more embodiments, the third member may include a plurality of parts separable in a vertical direction. This structure includes the third member separable into smaller parts and thus facilitates placement of the third member along the inner surface of the second member.

In one or more embodiments, the ceiling included in the first member may be circular and have a diameter larger than an inner diameter of an upper end of the third member. This structure reduces the likelihood that the inner surface of the second member is exposed to the processing space.

An inner chamber assembly according to one or more embodiments is an inner chamber assembly installable in a chamber in a substrate processing device. The inner chamber assembly includes a first member including a ceiling located above a substrate support to receive a substrate, and a second member including a side wall and supporting the first member. The second member is electrically connected to a ground member that is grounded and surrounds the substrate support. The first member and the second member are individual members and separable from each other.

Exemplary embodiments will now be described in detail with reference to the drawings. In the figures, like reference numerals denote like or corresponding components.

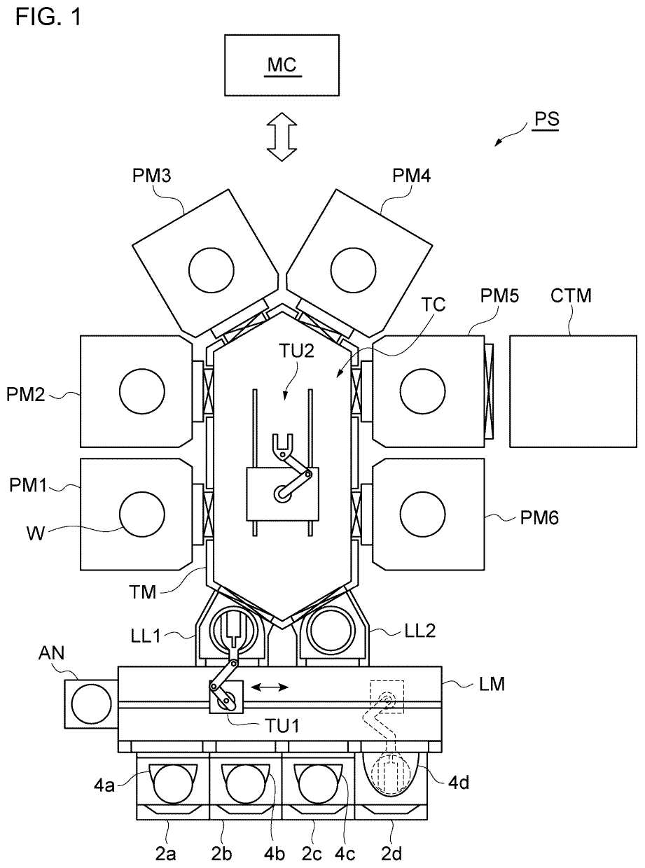

FIG. 1 is a diagram of a substrate processing system including an inner chamber assembly according to one or more embodiments. A substrate processing system PS shown in FIG. 1 includes process modules PM1 to PM6, a transfer module CTM, and a controller MC. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

The substrate processing system PS may further include tables 2a to 2d, containers 4a to 4d, an aligner AN, loadlock modules LL1 and LL2, and a transfer module TM. The substrate processing system PS may include one or more tables, one or more containers, and one or more loadlock modules. The substrate processing system PS may include one or more process modules.

The tables 2a to 2d are arranged along one edge of a loader module LM. The containers 4a to 4d are mounted on the respective tables 2a to 2d. The containers 4a to 4d are, for example, containers called front-opening unified pods (FOUPs). The containers 4a to 4d store substrates W.

The loader module LM includes a chamber. The chamber in the loader module LM has an atmospheric pressure. The loader module LM includes a transfer unit TU1. The transfer unit TU1 is, for example, a transfer robot controlled by the controller MC. The transfer unit TU1 transfers the substrate W through the chamber in the loader module LM. The transfer unit TU1 may transfer the substrate W between the containers 4a to 4d and the aligner AN, between the aligner AN and the loadlock modules LL1 and LL2, and between the loadlock modules LL1 and LL2 and the containers 4a to 4d. The aligner AN is connected to the loader module LM. The aligner AN adjusts (corrects) the position of the substrate W.

The loadlock modules LL1 and LL2 are located between the loader module LM and the transfer module TM. The loadlock modules LL1 and LL2 serve as preliminary decompression chambers. The loadlock modules LL1 and LL2 are connected to the loader module LM with gate valves. The loadlock modules LL1 and LL2 are connected to the transfer module TM with the gate valves.

The transfer module TM includes a decompressible transfer chamber TC. The transfer module TM includes a transfer unit TU2. The transfer unit TU2 is, for example, a transfer robot controlled by the controller MC. The transfer unit TU2 transfers the substrate W through the transfer chamber TC. The transfer unit TU2 may transfer the substrate W between the loadlock modules LL1 and LL2 and the process modules PM1 to PM6, and between any two of the process modules PM1 to PM6.

The process modules PM1 to PM6 are connected to the transfer module TM with gate valves. The process modules PM1 to PM6 are dedicated to intended substrate processing. At least one of the process modules PM1 to PM6 is a substrate processing device according to an exemplary embodiment (described later).

The transfer module CTM includes a chamber and a transfer unit. The transfer module CTM is controlled by the controller MC. The transfer module CTM includes the transfer unit. The transfer unit in the transfer module CTM transfers a second chamber located in a first chamber in the substrate processing device into the chamber in the transfer module CTM.

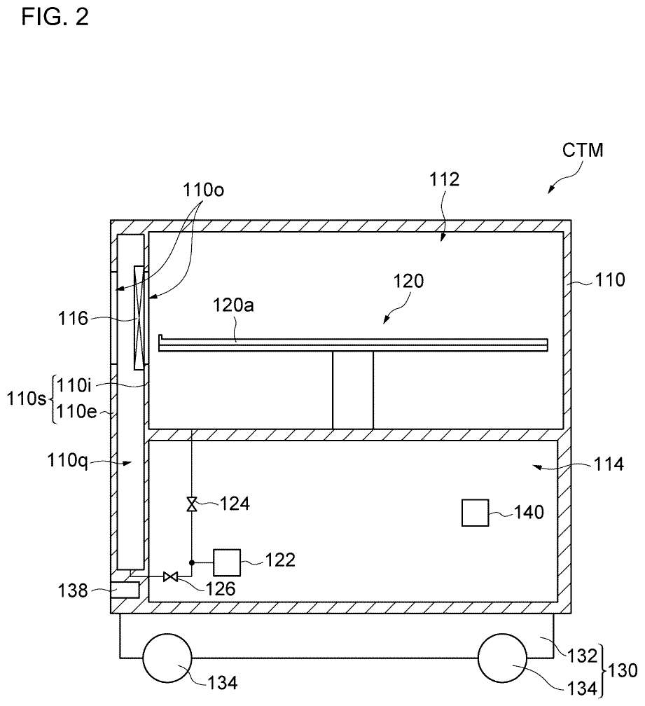

FIG. 2 is a schematic diagram of the transfer module in the substrate processing system according to one or more embodiments. The transfer module CTM includes a chamber 110. The chamber 110 has an internal space 112 and an internal space 114. The internal space 112 is located above the internal space 114 and separate from the internal space 114. The chamber 110 includes a side wall 110s having openings 110o continuous with the internal space 112. The openings 110o can be open and closed by a gate valve 116.

In one or more embodiments, the side wall 110s partially has a double structure including an inner side wall 110i and an outer side wall 110e. The inner side wall 110i and the outer side wall 110e define a space 110q between them. The openings 110o are located in the inner side wall 110i and the outer side wall 110e. The gate valve 116 extends along the inner side wall 110i to open and close the openings 110o.

The transfer module CTM further includes a transfer unit 120. The transfer unit 120 is a transfer robot and includes an arm 120a. The transfer unit 120 is located in the internal space 112.

The transfer module CTM further includes an exhaust device 122. The exhaust device 122 is located in the internal space 114. The exhaust device 122 is connected to the internal space 112 with a valve 124 and connected to the space 110q with a valve 126. The exhaust device 122 decompresses the internal space 112 and the space 110q.

The transfer module CTM further includes a mover 130. The mover 130 includes a body 132 and multiple wheels 134. The body 132 incorporates a power supply, such as a battery, a power source, and a steering assembly. The wheels 134 are rotatable by the power source in the body 132 to move the transfer module CTM in a direction controlled by the steering assembly in the body 132. The mover 130 for moving the transfer module CTM may have any structure, such as a walk-behind mover, other than the structure with wheels.

The transfer module CTM further includes a sensor 138 and a controller 140. The sensor 138 is installed on an outer wall of the chamber 110. The controller 140 is located in the internal space 114. The sensor 138 senses the surrounding environment of the transfer module CTM and outputs the sensing result to the controller 140. The sensor 138 is, for example, an image sensor and outputs an image of the surroundings of the transfer module CTM to the controller 140. The controller 140 may be a computer including a processor, a storage, such as a memory, and a communicator. The controller 140 controls the components of the transfer module CTM. The controller 140 controls the mover 130 using the sensing result from the sensor 138 and moves the transfer module CTM to connect the transfer module CTM to a substrate processing device 1. The controller 140 also controls the exhaust device 122 and the valves 124 and 126.

The controller MC controls the components of the substrate processing system PS. The controller MC may be a computer including a processor, a storage, an input device, and a display. The controller MC executes a control program stored in the storage to control the components of the substrate processing system PS based on recipe data stored in the storage.

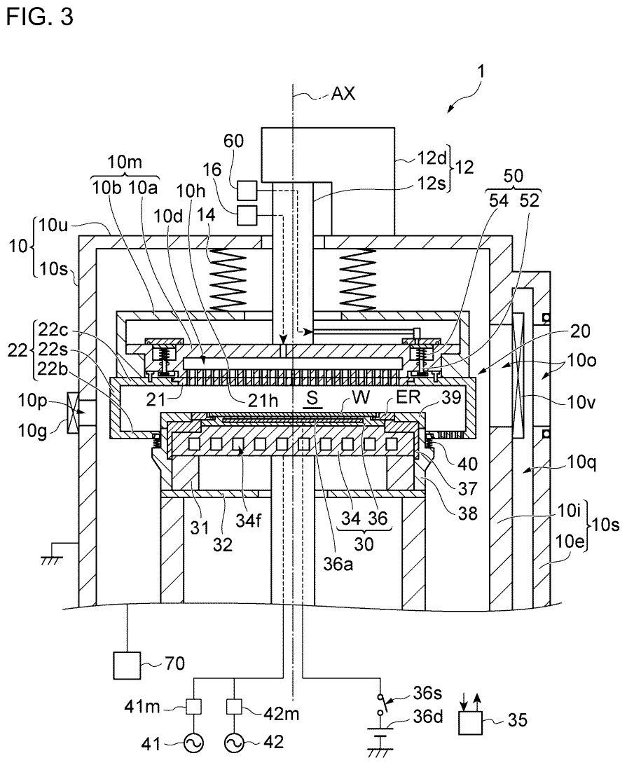

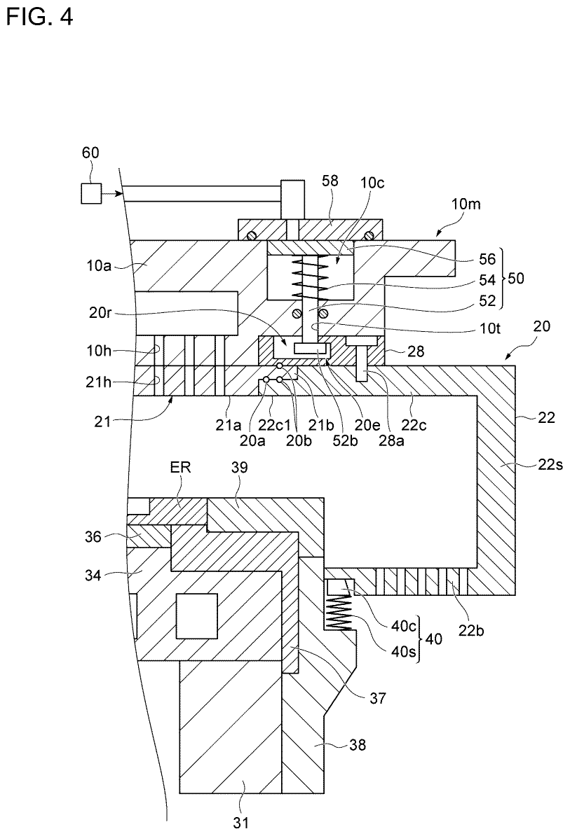

A substrate processing device according to an exemplary embodiment will now be described. FIG. 3 is a schematic diagram of a substrate processing device according to one or more embodiments. FIG. 4 is a partially enlarged cross-sectional view of the substrate processing device according to one or more embodiments. The substrate processing device 1 shown in FIGS. 3 and 4 is a capacitively coupled plasma processing device. The substrate processing device 1 includes a first chamber 10, a second chamber 20 (inner chamber assembly), and a substrate support 30.

The first chamber 10 has an internal space. The first chamber 10 is formed from a metal, such as aluminum. The first chamber 10 is electrically grounded. The first chamber 10 may have an anticorrosive film on its surface. The anticorrosive film is formed from, for example, a material, such as aluminum oxide or yttrium oxide.

The first chamber 10 includes a side wall 10s. The side wall 10s is substantially cylindrical. The side wall 10s has a central axis extending in the vertical direction and indicated by an axis AX in FIG. 3. The side wall 10s has a port 10p. The internal space of the first chamber 10 is connected to the internal space of the transfer chamber TC in the transfer module TM with the port 10p. The port 10p is open and closed by a gate valve 10g. The substrate W is transferred between the internal space of the first chamber 10 and the outside of the first chamber 10 through the port 10p.

The side wall 10s further has openings 100. The openings 100 are sized to allow the second chamber 20 to pass through. The internal space of the first chamber 10 is connectable to the internal space of the transfer module CTM through the openings 100. The openings 100 are open and closed by a gate valve 10v.

In one or more embodiments, the side wall 10s partially has a double structure including an inner side wall 10i and an outer side wall 10e. The inner side wall 10i and the outer side wall 10e define a space 10q between them. The openings 100 are located in the inner side wall 10i and the outer side wall 10e. The gate valve 10v extends along the inner side wall 10i to open and close the openings 100.

The first chamber 10 may further include an upper portion 10u. The upper portion 10u extends from an upper end of the side wall 10s in a direction intersecting with the axis AX. The upper portion 10u has an opening in an area intersecting with the axis AX.

The first chamber 10 further includes a movable unit 10m. The movable unit 10m is located below the upper portion 10u in the first chamber 10 and inward from the side wall 10s. The movable unit 10m is movable vertically in the first chamber 10.

The substrate processing device 1 further includes a lifter 12. The lifter 12 vertically moves the movable unit 10m. The lifter 12 includes a drive 12d and a shaft 12s. The movable unit 10m is fixed to the shaft 12s. The shaft 12s extends upward from the movable unit 10m through the opening in the upper portion 10u. The drive 12d is located outside the first chamber 10. The drive 12d vertically moves the shaft 12s. The drive 12d may include, for example, a motor for moving the shaft 12s. The shaft 12s vertically moves to vertically move the movable unit 10m.

The substrate processing device 1 may further include a bellows 14. The bellows 14 is located between the movable unit 10m and the upper portion 10u. The bellows 14 separates the internal space of the first chamber 10 from the outside of the first chamber 10. The bellows 14 has its lower end fixed to the movable unit 10m and its upper end fixed to the upper portion 10u.

In one or more embodiments, the movable unit 10m may include a first member 10a and a second member 10b. The first member 10a and the second member 10b are fixed to each other. The first member 10a is substantially disk-shaped. The first member 10a may serve as an upper electrode in the substrate processing device 1. The second member 10b is substantially disk-shaped. The second member 10b extends along the outer circumference of the first member 10a and above the first member 10a. The bellows 14 described above has its lower end fixed to the upper end of the second member 10b. The first member 10a and the second member 10b are formed from a conductor, such as aluminum. The first member 10a and the second member 10b may be electrically connected to the first chamber 10.

In one or more embodiments, the movable unit 10m may serve as a shower head together with the second chamber 20. In other words, the movable unit 10m may be a part of the shower head that supplies a gas to a processing space S (described later). In this embodiment, the movable unit 10m has a gas-diffusion compartment 10d and multiple gas holes 10h.

The gas-diffusion compartment 10d may be defined in the first member 10a. The gas-diffusion compartment 10d is connected to a gas supply 16. The gas supply 16 is external to the first chamber 10. The gas supply 16 includes one or more gas sources, one or more flow controllers, and one or more valves used in the substrate processing device 1. Each gas source is connected to the gas-diffusion compartment 10d through the corresponding flow controller and the corresponding valve. The gas holes 10h extend downward from the gas-diffusion compartment 10d.

The substrate support 30 (substrate support) is located in the first chamber 10 and below the movable unit 10m. The substrate support 30 supports the substrate W received on the substrate support 30. The substrate support 30 may be supported by a support 31. The support 31 is substantially cylindrical. The support 31 is formed from an insulator, such as quartz. The support 31 may extend upward from a bottom plate 32. The bottom plate 32 may be formed from a metal, such as aluminum.

The substrate support 30 may include a lower electrode 34 and an electrostatic chuck (ESC) 36. The lower electrode 34 is substantially disk-shaped. The lower electrode 34 has its central axis substantially aligned with the axis AX. The lower electrode 34 is formed from a conductor, such as aluminum. The lower electrode 34 has an internal channel 34f. The channel 34f extends, for example, spirally. The channel 34f is connected to a chiller unit 35. The chiller unit 35 is located outside the first chamber 10. The chiller unit 35 supplies a refrigerant to the channel 34f. The refrigerant supplied to the channel 34f returns to the chiller unit 35.

The substrate processing device 1 may further include a first RF power supply 41 and a second RF power supply 42. The first RF power supply 41 generates first RF power. The first RF power has a frequency suitable for generating plasma. The first RF power has a frequency higher than or equal to, for example, 27 MHz. The first RF power supply 41 is electrically coupled to the lower electrode 34 through a matcher 41m. The matcher 41m includes a matching circuit for matching the impedance of a load (lower electrode 34) for the first RF power supply 41 and the output impedance of the first RF power supply 41. The first RF power supply 41 may be coupled to the upper electrode through the matcher 41m rather than to the lower electrode 34.

The second RF power supply 42 generates second RF power. The second RF power has a frequency suitable for drawing ions toward the substrate W. The second RF power has a frequency lower than or equal to, for example, 13.56 MHz. The second RF power supply 42 is electrically coupled to the lower electrode 34 through a matcher 42m. The matcher 42m includes a matching circuit for matching the impedance of a load (lower electrode 34) for the second RF power supply 42 and the output impedance of the second RF power supply 42.

The ESC 36 is located on the lower electrode 34. The ESC 36 includes a body and an electrode 36a. The body of the ESC 36 is substantially disk-shaped. The ESC 36 has a central axis substantially aligned with the axis AX. The body of the ESC 36 is formed from ceramic. The substrate W is placed on the upper surface of the body of the ESC 36. The electrode 36a is a film formed from a conductor. The electrode 36a is located in the body of the ESC 36. The electrode 36a is coupled to a direct current (DC) power supply 36d through a switch 36s. A DC voltage is applied from the DC power supply 36d to the electrode 36a to generate an electrostatic attraction between the ESC 36 and the substrate W. The electrostatic attraction causes the ESC 36 to attract and hold the substrate W. The substrate processing device 1 may have a gas line to supply a heat transfer gas (e.g., a helium gas) to a space between the ESC 36 and the back surface of the substrate W.

The substrate support 30 may support an edge ring ER placed on the substrate support 30. The substrate W is placed on the ESC 36 in an area surrounded by the edge ring ER. The edge ring ER is formed from, for example, silicon, quartz, or silicon carbide.

The substrate processing device 1 may further include an insulator 37. The insulator 37 is formed from an insulator, such as quartz. The insulator 37 may be substantially cylindrical. The insulator 37 extends along the outer peripheries of the lower electrode 34 and the ESC 36.

The substrate processing device 1 may further include a conductor 38. The conductor 38 is formed from a conductor, such as aluminum. The conductor 38 may be substantially cylindrical. The conductor 38 extends along the outer periphery of the substrate support 30. More specifically, the conductor 38 is located outward from the insulator 37 in the radial direction and extends in the circumferential direction. The radial direction and the circumferential direction refer to the directions with respect to the axis AX. The conductor 38 is grounded. In one example, the conductor 38 is grounded through the bottom plate 32 and the first chamber 10.

The substrate processing device 1 may further include a cover ring 39. The cover ring 39 is formed from an insulator, such as quartz. The cover ring 39 is annular. The cover ring 39 is located on the insulator 37 and the conductor 38 to be located radially outward from an area in which the edge ring ER is located.

The second chamber 20 is an inner chamber assembly located in the first chamber 10 in the substrate processing device 1 and defining the processing space S together with the substrate support 30. The second chamber 20 is removable from the first chamber 10 and transferable between the internal space of the first chamber 10 and the outside of the first chamber 10 through the openings 100. The second chamber 20 in one or more embodiments includes a first member 21 and a second member 22. The first member 21 and the second member 22 are individual members and are separable from each other.

The first member 21 may be located above the substrate support 30 on which the substrate W is placed and form the ceiling defining the processing space S. The first member 21 in the illustrated example includes a disk-shaped body 21a extending substantially horizontally, and a protruding edge 21b along the edge of the body 21a. The body 21a has an upper surface in contact with the lower surface of the movable unit 10m when the second chamber 20 is fastened to the first chamber 10. The body 21a has multiple gas holes 21h. The gas holes 21h extend through the body 21a and are open toward the processing space S. The gas holes 21h are connected to the respective gas holes 10h.

The protruding edge 21b on the first member 21 is an annular portion protruding radially outward from the edge of the body 21a. The protruding edge 21b extends adjacent to the upper surface of the body 21a along the edge of the body 21a. In other words, the first member 21 has an edge stepped with its upper surface protruding outward with respect to its lower surface.

The first member 21 may be formed from a material that is less likely to produce particles (low contamination material). For example, the first member 21 may be formed from a Si-containing material. In one example, the first member 21 may be formed from a material, such as Si, SiC, SiO₂, and Si₃N₄. The first member 21 may have an anticorrosive film on its surface. The anticorrosive film is formed from, for example, a material, such as aluminum oxide or yttrium oxide.

The second member 22 may include a side wall defining the processing space S and support the first member 21. The second member 22 may be formed from a material different from the material of the first member 21. For example, the second member 22 may be formed from a material with a higher conductivity than the material of the first member 21. The second member 22 in one example is formed from a metal material, such as aluminum.

The second member 22 in one example includes a top portion 22c, a side portion 22s, and a bottom portion 22b. The top portion 22c is an annular plate. The top portion 22c includes an annular protruding edge 22c1 protruding radially inward from the inner edge. The protruding edge 22c1 is located adjacent to the lower surface of the top portion 22c along the inner edge of the top portion 22c. In other words, the top portion 22c has an inner edge stepped with its lower surface protruding outward with respect to its upper surface. The upper surface of the top portion 22c may have an inner diameter substantially the same as or slightly larger than the diameter of the upper surface of the first member 21. The lower surface of the top portion 22c may have an inner diameter substantially the same as or slightly larger than the diameter of the lower surface of the first member 21. The lower surface of the top portion 22c may have an inner diameter smaller than the diameter of the upper surface of the first member 21. This structure causes the protruding edge 22c1 on the second member 22 to be engaged with the protruding edge 21b on the first member 21, allowing the first member 21 to be supported by the second member 22. That is, the protruding edge 21b of the first member 21 can contact and overlap a protruding edge 22c1 of the second member 22, such that the protruding edge 21b of the first member engages the protruding edge 22c1 of the second member 22.

The side portion 22s extends to surround the processing space S. The side portion 22s is substantially cylindrical. The side portion 22s extends downward from the outer edge of the top portion 22c.

The bottom portion 22b extends from the lower end of the side portion 22s in a direction intersecting with the axis AX. The bottom portion 22b is an annular plate and faces the top portion 22c across the processing space S. As viewed in a direction along the axis AX, the bottom portion 22b has an outer edge aligned with the outer edge of the side portion 22s and an inner edge aligned with the outer edge of the conductor 38. The bottom portion 22b may have multiple through-holes. The substrate processing device 1 may further include an exhaust device 70. The exhaust device 70 includes a pressure regulator, such as an automatic pressure control valve and a decompression pump, such as a turbomolecular pump. The exhaust device 70 is connected to the bottom portion of the first chamber 10 below the bottom portion 22b.

The second member 22 may be electrically connected to a ground member that is grounded and surrounds the substrate support 30. In other words, the second member 22 is grounded. In one or more embodiments, the second member 22 is electrically connected to the conductor 38 serving as the ground member. In the illustrated example, a contact 40 in the substrate processing device 1 electrically connects the second member 22 to the conductor 38.

The contact 40 is electrically connected to the conductor 38. The second member 22 is in contact with the contact 40 when defining the processing space S together with the substrate support 30. The processing space S is a space in which the substrate W is processed. In one or more embodiments, the contact 40 is located radially outward from the cover ring 39 and extends upward from the conductor 38.

The contact 40 may be elastically in contact with the second member 22. As shown in FIG. 4, the contact 40 may include a spring 40s. The contact 40 may further include a contact portion 40c. The spring 40s and the contact portion 40c are conductive. The spring 40s has its lower end fixed to the conductor 38. The spring 40s extends upward from the conductor 38. The contact portion 40c is fixed to the upper end of the spring 40s. The contact portion 40c is in contact with the bottom portion 22b of the second member 22. In the illustrated example, the bottom portion 22b of the second member 22 has a groove receiving the contact portion 40c. In one or more embodiments, the second chamber 20 may include a connector 28 to fasten the first member 21 and the second member 22. The connector 28 may be formed from, for example, the same material as the second member 22. The connector 28 in one example may be an annular plate. The connector 28 in the illustrated example has an inner diameter equal to the inner diameter of the lower surface of the top portion 22c in the second member 22 and smaller than the outer diameter of the top portion 22c in the second member 22. The connector 28 may have through-holes at positions close to its outer edge to receive fasteners 28a, such as screws. In this case, the top portion 22c in the second member 22 may have threaded holes at positions corresponding to the through-holes. The connector 28 is fastened to the second member 22 with the fasteners 28a received in the through-holes. The protruding edge 21b on the first member 21 is held between the connector 28 and the protruding edge 22c1 on the second member 22 to fasten the first member 21 to the second member 22 and the connector 28.

In the illustrated example, a sealing member 20a (e.g., O-ring) is located between the protruding edge 21b on the first member 21 and the protruding edge 22c1 on the second member 22. When the first member 21 is formed from a conductive material, contact members 20b may be located between the protruding edge 21b on the first member 21 and the protruding edge 22c1 on the second member 22 and between the first member 21 and the connector 28. Each contact member 20b electrically connects the first member 21, the second member 22, and the connector 28 to one another. The contact member 20b may be located radially outward from the sealing member 20a.

The substrate processing device 1 further includes a clamp 50 and a releaser 60. The clamp 50 releasably fastens the second chamber 20 to the first chamber 10. The releaser 60 releases the second chamber 20 fastened with the clamp 50. The clamp 50 releasably fastens the connector 28 in the second chamber 20 to the movable unit 10m in the first chamber 10.

As shown in FIGS. 3 and 4, the clamp 50 includes multiple supports 52 and multiple springs 54 in one or more embodiments. The clamp 50 may further include a plate 56. The clamp 50 may include a single support 52 and a single spring 54.

Each support 52 has a lower end 52b. The lower end 52b suspends the connector 28. The springs 54 urge the connector 28 toward the movable unit 10m in the first chamber 10.

In one or more embodiments, the movable unit 10m in the first chamber 10 has a cavity 10c. The cavity 10c may extend in the circumferential direction about the axis AX. The cavity 10c is closed with a lid 58. The lid 58 is located on the movable unit 10m in the first chamber 10 to close the cavity 10c. The movable unit 10m further has multiple holes 10t. The holes 10t may be arranged at equal intervals about the axis AX. The holes 10t extend downward from the cavity 10c and are open toward the connector 28. The connector 28 includes multiple recessed portions 20r. The recessed portions 20r are connected to the respective holes 10t when the second chamber 20 is fastened to the first chamber 10.

In one or more embodiments, the supports 52 are rods. The lower end 52b of each support 52 protrudes in the horizontal direction. Each recessed portion 20r has a bottom including an extension 20e. The extension 20e may receive the lower end 52b of the corresponding one of the multiple supports 52. In one example, each support 52 may be a screw and have the lower end 52b that is the head of the screw.

The supports 52 extend downward from the cavity 10c through the holes 10t. When the top portion 22c is suspended from the supports 52, the lower ends 52b of the supports 52 are located in the respective recessed portions 20r and the extensions 20e in the recessed portions 20r.

The upper ends of the supports 52 are fixed to the plate 56 in the cavity 10c. The springs 54 are located in the cavity 10c. The springs 54 are located between the surface of the movable unit 10m defining the cavity 10c from below and the plate 56. In one or more embodiments, the springs 54 are coil springs. The springs 54 surround the supports 52 in the cavity 10c.

In one or more embodiments, the releaser 60 includes an air supply. The air supply applies an air pressure to separate the lower end 52b of each support 52 from the second chamber 20 to release the connector 28 fastened with the clamp 50. The air supply in the releaser 60 may supply air to a space between the lid 58 and the plate 56. When air is supplied to the space between the lid 58 and the plate 56, the plate 56 and the supports 52 move downward, separating the lower end 52b of each support 52 from the second chamber 20. Thus, the connector 28 fastened with the clamp 50 is released. When the connector 28 fastened with the clamp 50 is released, the second chamber 20 fastened to the first chamber 10 is released to allow the second chamber 20 to be transferred from the internal space of the first chamber 10 to the outside of the first chamber 10.

A method for removing the second chamber 20 will now be described. The second chamber 20 may be removed from the first chamber 10 and transferred from the internal space of the first chamber 10 to the internal space of the chamber 110 in the transfer module CTM for, for example, maintenance. The controller MC may control the operation of the substrate processing device 1. The controller 140 may control the operation of the transfer module CTM. The controller 140 may control the transfer module CTM based on information, such as a command transmitted from the controller MC.

In one example, the transfer module CTM is first moved to connect the chamber 110 in the transfer module CTM to the first chamber 10 in the substrate processing device 1. When the chamber 110 is connected to the first chamber 10, the side wall 10s, the gate valve 10v, the side wall 110s, and the gate valve 116 define a sealed space. The sealed space includes the space 10q and the space 110q. The sealed space is decompressed by the exhaust device 122. At the same time, the internal space 112 of the chamber 110 in the transfer module CTM is also decompressed by the exhaust device 122.

The gate valve 10v and the gate valve 116 then move to connect the internal space of the first chamber 10 and the internal space 112 of the chamber 110 in the transfer module CTM. The lifter 12 then separates the movable unit 10m and the second chamber 20 upward from the substrate support 30 in the first chamber 10. The arm 120a in the transfer unit 120 then enters the internal space of the first chamber 10 to extend to a portion below the second chamber 20. The lifter 12 moves the movable unit 10m and the second chamber 20 downward to place the second chamber 20 on the arm 120a. The releaser 60 then releases the second chamber 20 fastened with the clamp 50. The transfer unit 120 moves the second chamber 20 in the horizontal direction to retract the lower ends 52b of the supports 52 from the extensions 20e. The lifter 12 then moves the movable unit 10m upward to separate the movable unit 10m from the second chamber 20. This moves the lower ends 52b of the supports 52 out of the recessed portions 20r. The arm 120a in the transfer unit 120 then moves the second chamber 20 from the internal space of the first chamber 10 to the internal space 112 of the chamber 110 in the transfer module CTM through the openings 100 and the openings 110o. The gate valves 10v and 116 then move to close the openings 100 and the openings 110o.

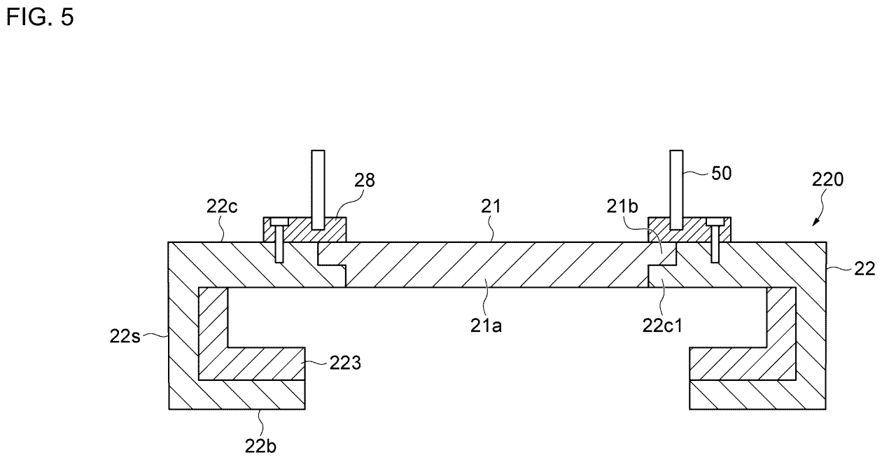

A second chamber in one or more embodiments will now be described with reference to FIGS. 5 to 9. The structures not described below and not shown in the figures may be the same as the structures of the second chamber 20 shown in FIGS. 3 and 4. FIG. 5 is a schematic diagram of a second chamber 220 that is an inner chamber assembly in one or more embodiments. The second chamber 220 shown in FIG. 5 includes the first member 21, the second member 22, and the connector 28 included in the second chamber 20 shown in FIGS. 3 and 4.

The second chamber 220 further includes a third member 223. The third member 223 may be formed from, for example, the same material as the first member 21. The third member 223 may be annular and may extend along the inner surface of the side portion 22s (side wall) in the second member 22. The third member 223 in the illustrated example is substantially L-shaped in a cross-sectional view, and extends along the inner surfaces of the side portion 22s and the bottom portion 22b in the second member 22. In this case, the second member 22 or the third member 223 may include multiple parts combined together.

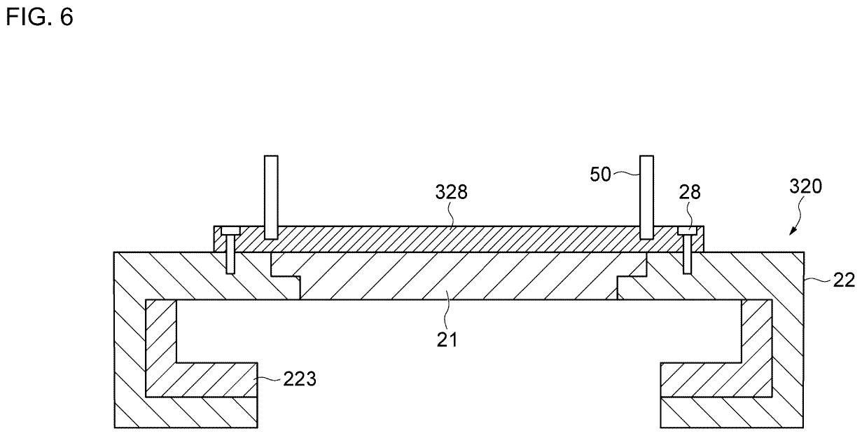

FIG. 6 is a schematic diagram of a second chamber 320 that is an inner chamber assembly in still one or more embodiments. The second chamber 320 shown in FIG. 6 differs from the second chamber 220 shown in FIG. 5 in the structure of a connector 328. More specifically, the second chamber 320 includes the connector 328, in addition to the first member 21, the second member 22, and the third member 223. The connector 328 covers an upper portion (upper surface) of the first member 21.

The connector 328 may be formed from, for example, the same material as the second member 22. The connector 328 in one example may be disk-shaped. The connector 328 in the illustrated example has a diameter larger than the diameter of the upper surface of the first member 21 and smaller than the outer diameter of the second member 22. The connector 328 has through-holes similarly to the connector 28 in FIG. 4, and is fastened to the second member 22 with the fasteners 28a received in the through-holes.

The upper surface of the connector 328 is in contact with the lower surface of the movable unit 10m when the second chamber 320 is fastened to the first chamber 10. The lower surface of the connector 328 is in contact with the upper surface of the first member 21. The connector 328 thus has multiple gas holes. The gas holes extend through the connector 328 and are connected to the gas holes 10h in the first chamber 10 and the gas holes 21h in the first member 21.

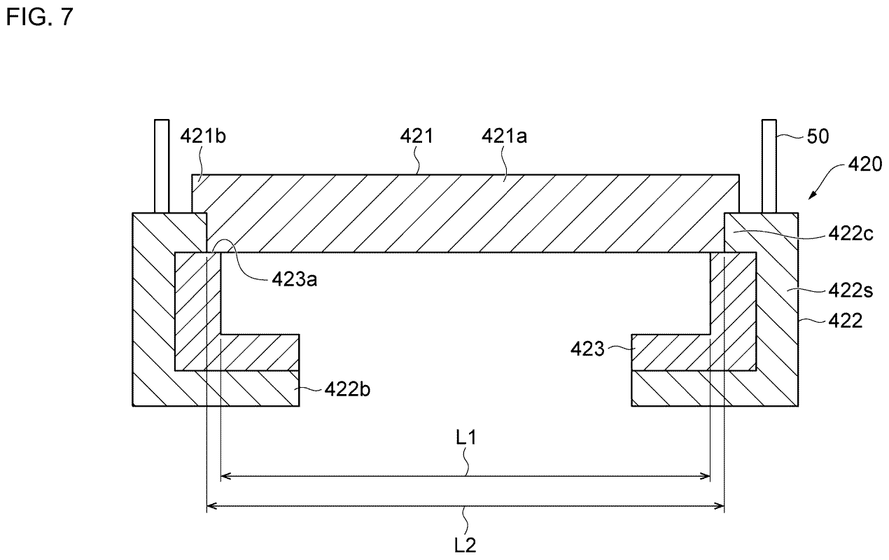

FIG. 7 is a schematic diagram of a second chamber 420 that is an inner chamber assembly in still one or more embodiments. The second chamber 420 includes a first member 421 and a second member 422. The first member 421 and the second member 422 are individual members and are separable from each other. The first member 421 may be formed from the same material as the first member 21. The second member 422 may be formed from, for example, the same material as the second member 22.

The first member 421 is located above the substrate support 30 on which the substrate W is placed and forms the ceiling defining the processing space S. The first member 421 in the illustrated example includes a disk-shaped body 421a that extends substantially horizontally, and a protruding edge 421b along the edge of the body 421a. The protruding edge 421b extends adjacent to the upper surface of the body 421a along the edge of the body 421a. In other words, the edge of the first member 421 is stepped with its upper surface protruding outward with respect to its lower surface.

The second member 422 may include a side wall defining the processing space S and support the first member 421. The second member 422 in one example includes a top portion 422c, a side portion 422s, and a bottom portion 422b. The top portion 422c is an annular plate. The top portion 422c has an inner diameter smaller than the diameter of the upper surface of the first member 421 and larger than the diameter of the lower surface of the first member 421. This structure may allow the protruding edge 421b on the first member 421 to be engaged with the inner peripheral edge of the second member 422, and the first member 421 to be supported by the second member 422.

The side portion 422s and the bottom portion 422b may have the same shape as the side portion 22s and the bottom portion 22b in the second chamber 20. The inner surfaces of the side portion 422s and the bottom portion 422b may be covered with a third member 423. The third member 423 may be formed from, for example, the same material as the second member 22. The third member 423 may be annular and may extend along the inner surface of the side portion 422s (side wall) in the second member 422. The third member 423 in the illustrated example is substantially L-shaped in a cross-sectional view, and extends along the inner surfaces of the side portion 422s and the bottom portion 422b in the second member 422.

The ceiling (lower surface) formed by the first member 421 is circular and has a diameter larger than the inner diameter of the upper end of the third member 423. In the illustrated example, the third member 423 has an upper end face 423a in contact with the lower surface of the first member 421.

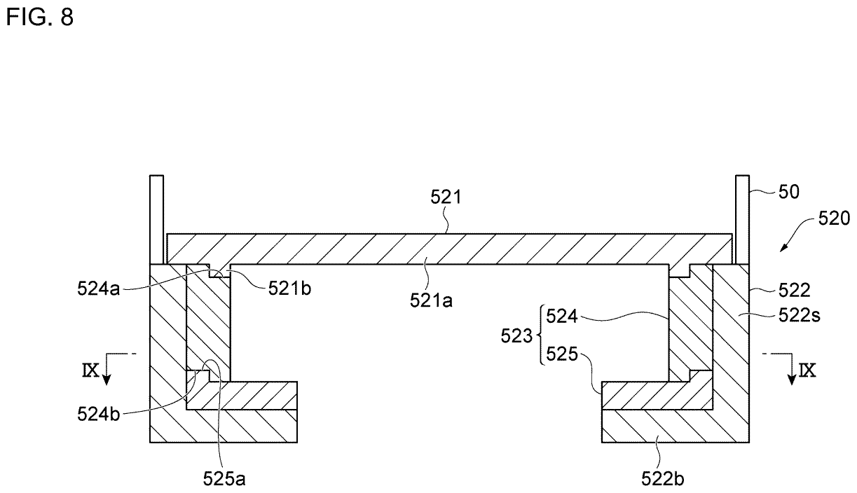

FIG. 8 is a schematic diagram of a second chamber 520 that is an inner chamber assembly in still one or more embodiments. The second chamber 520 includes a first member 521, a second member 522, and a third member 523. The first member 521, the second member 522, and the third member 523 are individual members and are separable from one another. The first member 521 and the third member 523 may be formed from, for example, the same material as the first member 21. The second member 522 may be formed from, for example, the same material as the second member 22.

The first member 521 may be located above the substrate support 30 on which the substrate W is placed and form the ceiling defining the processing space S. The first member 521 in the illustrated example includes a disk-shaped body 521a extending substantially horizontally, and an annular protrusion 521b protruding downward from the lower surface of the body 521a. The protrusion 521b has an outer diameter smaller than the diameter of the body 521a. In other words, the protrusion 521b is located inward from the periphery of the body 521a.

The second member 522 may include a side wall defining the processing space S and support the first member 521. The second member 522 in one example includes a side portion 522s and a bottom portion 522b. The side portion 522s is cylindrical. The side portion 522s has an inner diameter smaller than the diameter of the body 521a of the first member 521 and larger than the outer diameter of the protrusion 521b. This structure may allow the first member 521 to be supported on the upper end face of the side portion 522s in the second member 522. The bottom portion 522b may have the same shape as the bottom portion 22b in the second chamber 20. The side portion 522s may have the upper end face connectable to the clamp 50.

The third member 523 may be annular and extend along the inner surface of the side portion 522s in the second member 522. The third member 523 in the illustrated example is substantially L-shaped in a cross-sectional view, and extends along the inner surfaces of the side portion 522s and the bottom portion 522b in the second member 522.

The third member 523 may include multiple parts separable in the vertical direction. The third member 523 in one example may include a fourth member 524 that is cylindrical and a fifth member 525 that is an annular plate. In the illustrated example, the fourth member 524 covers the side portion 522s in the second member 522, and the fifth member 525 covers the bottom portion 522b in the second member 522. As shown in FIG. 8, the fourth member 524 may have a recess 524a (step) on its upper end. The protrusion 521b on the first member 521 is received in the recess 524a. The recess 524a is stepped along the inner circumference of the upper end face of the fourth member 524. The recess 524a may be a groove in a middle portion in the radial direction on the upper end face of the fourth member 524 or a step along the outer circumference of the upper end face.

The protrusion 521b on the first member 521 is defined by multiple planes intersecting with one another. Similarly, the recess 524a on the fourth member 524 is defined by multiple planes intersecting with one another. The planes defining the protrusion 521b on the first member 521 and the planes defining the recess 524a on the fourth member 524 are in contact with one another.

The fourth member 524 has a recess on its lower end to receive a protrusion 525a on the fifth member 525. In the illustrated example, the fifth member 525 includes the annular protrusion 525a protruding upward along its outer edge. A recess 524b on the fourth member 524 is stepped along the outer circumference of the lower end face of the side portion. The recess 524b may be a groove in a middle portion in the radial direction on the lower end face of the fourth member 524 or a step along the inner circumference of the lower end face. In these cases, the protrusion 525a on the fifth member 525 is located at a position corresponding to the recess 524b.

The recess 524b on the fourth member 524 is defined by multiple planes intersecting with one another. Similarly, the protrusion 525a on the fifth member 525 is also defined by multiple planes intersecting with one another. The planes defining the recess 524b on the fourth member 524 and the planes defining the protrusion 525a on the fifth member 525 are in contact with one another.

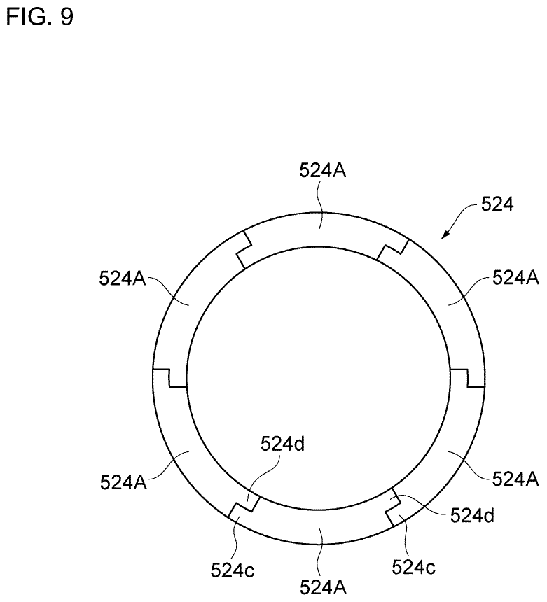

The third member 523 may include multiple parts separable in the circumferential direction. FIG. 9 is a cross-sectional view taken along line IX-IX in FIG. 8, showing a cross section of the fourth member 524 included in the third member 523. In FIG. 9, the hatching is not used for viewability. In one or more embodiments, as shown in FIG. 9, the fourth member 524 included in the third member 523 includes multiple parts 524A. The fourth member 524 in the illustrated example includes six parts 524A. The parts 524A included in the fourth member 524 have the same shape. Each part 524A has a shape obtained by cutting a cylinder in the circumferential direction. Each part 524A has a step 524d with an inner circumference protruding with respect to its outer circumference at one circumferential end (first end), and has a step 524c with an outer circumference protruding with respect to its inner circumference at the other circumferential end (second end). The steps 524d are defined by multiple planes intersecting with one another. Similarly, the steps 524c are also defined by multiple planes intersecting with one another. The adjacent steps 524d and 524c in the parts 524A adjacent to each other are fitted to each other. In other words, the planes defining the steps 524c and the planes defining the steps 524d are in contact with one another. Similarly to the fourth member 524, the fifth member 525 may include multiple parts.

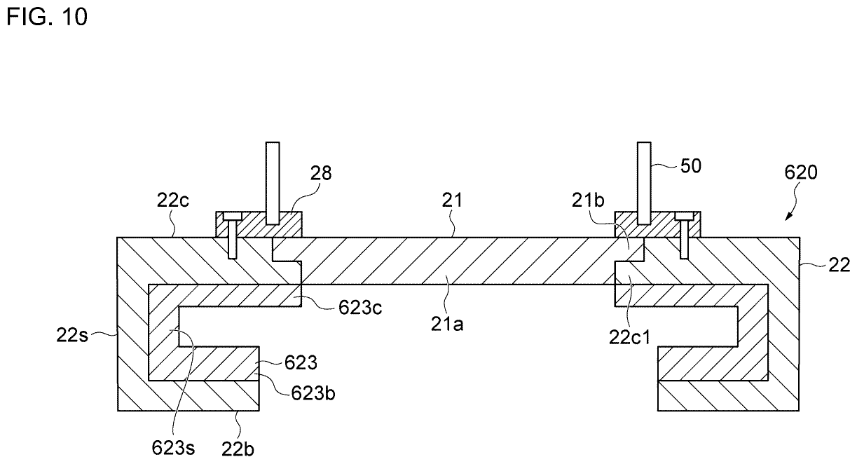

FIG. 10 is a schematic diagram of a second chamber 620 that is an inner chamber assembly in still one or more embodiments. The second chamber 620 shown in FIG. 10 includes the first member 21, the second member 22, and the connector 28 included in the second chamber 20 shown in FIGS. 3 and 4. The second chamber 620 may be located in the first chamber 10 in the substrate processing device 1 in place of the second chamber 20.

The second chamber 620 further includes a third member 623. The third member 623 may be formed from, for example, the same material as the first member 21. The third member 623 may be annular along the inner surface of the side portion 22s in the second member 22. For example, the third member 623 may be in contact with the inner surface of the second member 22. The third member 623 in the illustrated example extends along the inner surfaces of the side portion 22s, the bottom portion 22b, and the top portion 22c in the second member 22. More specifically, the third member 623 includes a side portion 623s, a bottom portion 623b, and a top portion 623c. The side portion 623s extends along the inner surface of the side portion 22s and covers the side portion 22s. The bottom portion 623b is connected to the lower end of the side portion 623s and covers the inner surface of the bottom portion 22b along the inner surface of the bottom portion 22b. The top portion 623c is connected to the upper end of the side portion 623s and covers the inner surface of the top portion 22c along the inner surface of the top portion 22c. The bottom portion 623b may have an inner edge at the same position as the inner edge of the bottom portion 22b in the radial direction. The top portion 623c may have an inner edge at the same position as the inner edge of the top portion 22c (specifically, the edge of the body 21a) in the radial direction. The second member 22 or the third member 623 may include multiple parts combined together.

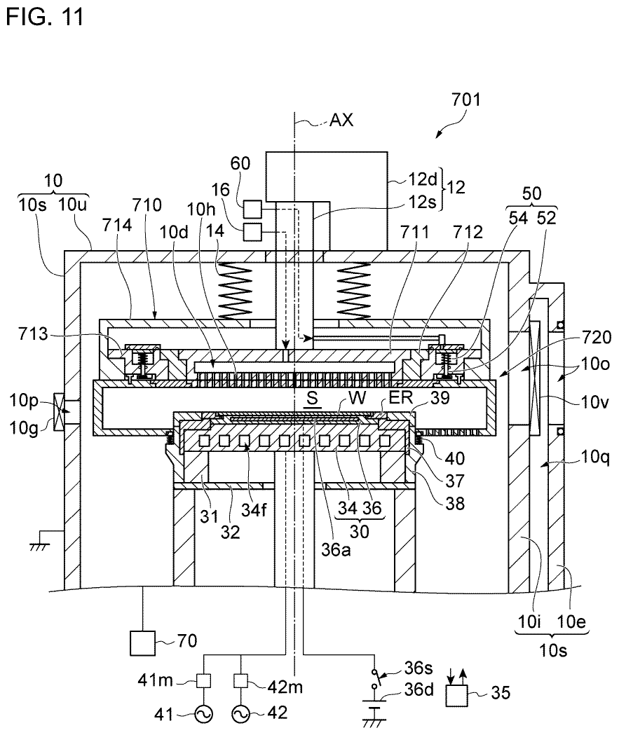

FIG. 11 is a schematic diagram of a substrate processing device 701 according to one or more embodiments. The substrate processing device 701 may be used as the process modules PM1 to PM6 in place of the substrate processing device 1. The substrate processing device 701 will be described focusing on the differences from the substrate processing device 1. The same structure as the substrate processing device 1 will not be described.

The substrate processing device 701 includes a movable unit 710 in place of the movable unit 10m in the substrate processing device 1. Similarly to the movable unit 10m, the movable unit 710 is fastened to the shaft 12s and moves vertically. In one or more embodiments, the movable unit 710 may include an electrode portion 711, an insulator 712, a fixture 713, and a support 714. The electrode portion 711, the insulator 712, the fixture 713, and the support 714 may be fixed to one another.

The electrode portion 711, the insulator 712, and the fixture 713 correspond to the first member 10a in the movable unit 10m. The support 714 corresponds to the second member 10b in the movable unit 10m. The electrode portion 711 is substantially disk-shaped and is formed from a conductor, such as aluminum. The electrode portion 711 has the gas-diffusion compartment 10d and the multiple gas holes 10h, similarly to the first member 10a. The electrode portion 711 may be coupled to the RF power supply to serve as an upper electrode.

The insulator 712 is substantially annular and extends in the circumferential direction about the axis AX. The insulator 712 is formed from an insulator, such as quartz. The insulator 712 surrounds the electrode portion 711 in the circumferential direction and supports the electrode portion 711. In one example, the electrode portion 711 may include, on the upper end of the outer edge, a flange supported on the upper end of the inner edge of the insulator 712. The insulator 712 may include a step corresponding to the flange. A space between the electrode portion 711 and the insulator 712 may be sealed with a sealing member, such as an O-ring.

The fixture 713 is substantially annular and extends in the circumferential direction about the axis AX. The fixture 713 includes the clamp 50, similarly to the first member 10a. The fixture 713 is formed from a conductor, such as aluminum. The fixture 713 surrounds the insulator 712 in the circumferential direction and supports the insulator 712. In one example, the insulator 712 may include, on the upper end of the outer edge, a flange supported on the upper end of the inner edge of the fixture 713. The fixture 713 may include a step corresponding to the flange. A space between the insulator 712 and the fixture 713 may be sealed with a sealing member, such as an O-ring. The insulator 712 between the electrode portion 711 and the fixture 713 electrically insulates the electrode portion 711 from the fixture 713.

The support 714 is substantially cylindrical. The support 714 is formed from a conductor, such as aluminum. The support 714 extends along the outer circumference of the fixture 713 and above the electrode portion 711, the insulator 712, and the fixture 713. The support 714 supports the fixture 713. In one example, the fixture 713 may include, on the upper end of the outer edge, a flange supported on the upper end of the inner edge of the support 714. A space between the fixture 713 and the support 714 may be sealed with a sealing member, such as an O-ring.

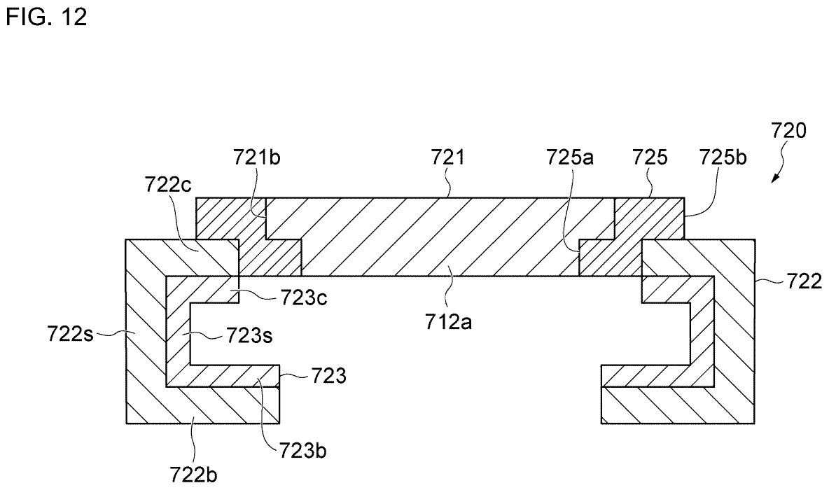

FIG. 12 is a schematic diagram of a second chamber that is an inner chamber assembly used in the substrate processing device 701 shown in FIG. 11. A second chamber 720 includes a first member 721, a second member 725, and a third member 722. The first member 721, the second member 725, and the third member 722 are individual members and are separable from one another. In FIG. 12, a portion of the movable unit 710 fastened by the clamp 50 is not shown. The movable unit 710 is fastened to the second chamber 720 in any manner.

The first member 721 may be formed from the same material as the first member 21. The first member 721 is located above the substrate support 30 on which the substrate W is placed and forms the ceiling defining the processing space S. The first member 721 in the illustrated example includes a disk-shaped body 721a extending substantially horizontally, and a protruding edge 721b along the edge of the body 721a. The protruding edge 721b extends adjacent to the upper surface of the body 721a along the edge of the body 721a. In other words, the edge of the first member 721 is stepped with its upper surface protruding outward with respect to its lower surface. The body 721a may have an upper surface in contact with the bottom surface of the electrode portion 711. The body 721a may have gas holes connected to the gas holes 10h. The first member 721 may have a groove receiving a contact member for electrical conduction (electrical connection) with the electrode portion 711. The groove may be located on the upper surface of the body 721a.

The second member 725 is formed from a dielectric member with a dielectric constant & higher than or equal to 3, for example, Al₂O₃, AlN, high-resistivity silicon, or SiC. The second member 725 is substantially annular and extends in the circumferential direction about the axis AX. The second member 725 surrounds the first member 721 in the circumferential direction and supports the first member 721. The second member 725 has an upper surface in contact with the bottom surface of the insulator 712. The second member 725 includes an annular protrusion 725a protruding radially inward to support the protruding edge 721b on the first member 721. A space between the first member 721 and the second member 725 may be sealed with a sealing member, such as an O-ring. The second member 725 has an annular protruding edge 725b protruding outward from its upper end.

The third member 722 may be formed from, for example, the same material as the second member 22. The third member 722 may include a side wall defining the processing space S and support the second member 725. The third member 722 in one example includes a top portion 722c, a side portion 722s, and a bottom portion 722b. The top portion 722c is an annular plate. The top portion 722c has an inner diameter smaller than the diameter of the protruding edge 725b on the second member 725 and larger than the diameter of the lower surface of the second member 725. This structure allows the protruding edge 725b on the second member 725 to be supported on the inner peripheral edge of the third member 722. The second member 725 between the first member 721 and the third member 722 electrically insulates the first member 721 from the third member 722. In this case, the electrode portion 711 is also insulated from the third member 722. A space between the second member 725 and the third member 722 may be sealed with a sealing member, such as an O-ring. Similarly to the second member 22, the third member may serve as a return path for RF waves.

The side portion 722s and the bottom portion 722b may have the same shape as the side portion 22s and the bottom portion 22b in the second chamber 20. The inner surfaces of the top portion 722c, the side portion 722s, and the bottom portion 722b may be covered with a nonconducting film of, for example, anodized aluminum, aluminum oxide, yttrium oxide, or other materials. The inner surfaces of the top portion 722c, the side portion 722s, and the bottom portion 722b may be covered with, for example, a fourth member 723. The fourth member 723 may be formed from, for example, the same material as the second member 22. The fourth member 723 may be annular and extend along the inner surface of the side portion 722s in the third member 722. Similarly to the third member 623 in the second chamber 620, the fourth member 723 in the illustrated example extends along the inner surfaces of the side portion 722s and the bottom portion 722b in the third member 722.

As described above, the second chamber 20 as the inner chamber assembly is provided in one or more embodiments. The second chamber 20 is installed in the first chamber 10 in the substrate processing device 1. The second chamber 20 includes the first member 21 including the ceiling located above the substrate support 30 to receive the substrate W, and the second member 22 including the side wall and supporting the first member 21. The second member 22 is electrically connected to the grounded conductor 38 surrounding the substrate support 30. The first member 21 and the second member 22 are individual members and are separable from each other.

In the second chamber 20, the substrate support 30, the first member 21 including the ceiling located above the substrate support 30, and the second member 22 including the side wall define the processing space S. The RF waves output from the first RF power supply 41 are returned through the second member 22 connected to the conductor 38 as the return path. In one example, the substrate support 30 on which the substrate W is placed includes the lower electrode 34, and the movable unit 10m on which the second chamber 20 is supported includes the upper electrode. The first member 21 in the second chamber 20 is located between the lower electrode 34 and the upper electrode, and is likely to wear. In one or more embodiments, the first member 21 and the second member 22 are individual members. The second chamber is disassembled to replace the worn first member 21 alone for maintenance. This reduces the cost for replacing the chamber defining the processing space S.

In one or more embodiments, the first member 21 and the second member 22 may be formed from different materials. In this structure, a material may be selected for each member based on, for example, intended functions. For example, the second chamber may include a support assembly in the second member 22. In this case, the second member 22 may be formed from a material with high machinability and resistance to fracture.

In one or more embodiments, the first member 21 may be formed from a Si-containing material. For example, the first member 21 may be formed from one of Si, SiC, SiO₂, or Si₃N₄. The second member 22 may be formed from a metal material. In this structure, the first member 21, which is likely to wear, is formed from a low contamination material, and the second member 22, which serves as the return path for RF waves, is formed from a metal material with low electrical resistance.

In one or more embodiments, the first member 21 may have the gas holes 21h. In this structure, the gas holes 21h are connected to the gas holes 10h to allow a gas to be easily supplied to the processing space S.

In one or more embodiments, the first member 21 may include the protruding edge 21b to be supported by the second member 22. This structure prevents the first member 21 from slipping off the second member 22. In one example, the second member 22 including the support structure allows the second chamber 20 to be supported by the movable unit 10m, and reduces an unintended external force applied to the first member 21 as a wearable component.

In one or more embodiments, the second chamber 220 may include the third member 223 located along the inner surface of the side wall in the second member 22. This structure reduces the likelihood of the inner surface of the second member 22 being exposed, thus reducing the likelihood of the second member 22 being worn.

In one or more embodiments, the third member 223 may be annular. This structure allows the inner surface of the second member 22 to be fully covered easily.

In one or more embodiments, the third member 523 may include multiple parts separable in the circumferential direction. The third member 523 may include multiple parts separable in the vertical direction. In this structure, the third member 523 includes smaller separable parts and thus facilitates placement of the third member 523 along the inner surface of the second member 22. The size of the third member as a wearable component is smaller, thus reducing the manufacturing cost. For example, a space between adjacent parts may be bent, rather than being straight (flat). This reduces the likelihood that the inner surface of the second member 22 is exposed to the processing space S.

In one or more embodiments, the ceiling formed by the first member 421 may be circular. The body 421a in the first member 421 forming the ceiling may have a lower surface with a diameter larger than the inner diameter of the upper end of the third member 423. This structure reduces the likelihood that the inner surface of the second member 422 is exposed to the processing space.

Although various exemplary embodiments have been described above, the embodiments are not restrictive, and various additions, omissions, substitutions, and changes may be made. The components in the different embodiments may be combined to form another embodiment.

In another embodiment, for example, the substrate processing device may be of another type, such as an inductively coupled plasma processing device, an electron cyclotron resonance (ECR) plasma processing device, or a plasma processing device that generates plasma using microwaves. In still another embodiment, the substrate processing device may perform substrate processing other than plasma processing.

The transfer module CTM may be immovable or connected and fixed to the first chamber in the substrate processing device including the second chamber 20. The transfer module TM may be used as a module for transferring the second chamber 20 from the internal space of the first chamber 10, in place of the transfer module CTM.

Although the clamp 50 supports the second chamber in the above structure, for example, the second chamber may include a protrusion protruding upward, and the movable unit 10m may support the protrusion. Although the contact 40 is electrically in contact with the second member in the above structure, for example, the second member 22 may include a contact on the bottom portion 22b, and the conductor 38 may include a recessed portion for receiving the contact.

Various exemplary embodiments according to the disclosure have been described by way of example, and various changes may be made without departing from the scope and spirit of the disclosure. One or more embodiments disclosed above are thus not restrictive, and the true scope and spirit of the disclosure are defined by the appended claims. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

Various exemplary embodiments included in the disclosure will now be described.

### E1

A substrate processing device, comprising:
a first chamber in which a substrate support to receive a substrate is located; and
a second chamber located in the first chamber, the second chamber including
   a first member including a ceiling located above the substrate support, and
   a second member including a side wall and supporting the first member, the second member being electrically connected to a ground member being grounded and surrounding the substrate support,
wherein the first member and the second member are individual members and separable from each other.

### E2

The substrate processing device according to E1, wherein
the first member and the second member comprise different materials.

### E3

The substrate processing device according to E2, wherein
the first member comprises a Si-containing material.

### E4

The substrate processing device according to E3, wherein
the first member comprises one of Si, SiC, SiO₂, or Si₃N₄, and
the second member comprises a metal material.

### E5

The substrate processing device according to any one of E1 to E4, wherein
the first member has a gas hole.

### E6

The substrate processing device according to any one of E1 to E5, wherein
the first member includes a protruding edge engaged with the second member.

### E7

The substrate processing device according to any one of E1 to E6, further comprising:
a third member located along an inner surface of the side wall in the second member.

### E8

The substrate processing device according to E7, wherein
the third member is annular.

### E9

The substrate processing device according to E8, wherein
the third member includes a plurality of parts separable in a circumferential direction.

### E10

The substrate processing device according to any one of E7 to E9, wherein
the third member includes a plurality of parts separable in a vertical direction.

### E11

The substrate processing device according to any one of E7 to E10, wherein
the ceiling included in the first member is circular and has a diameter larger than an inner diameter of an upper end of the third member.

### E12

An inner chamber assembly installable in a chamber in a substrate processing device, the inner chamber assembly comprising:
a first member including a ceiling located above a substrate support to receive a substrate; and
a second member including a side wall and supporting the first member, the second member being electrically connected to a ground member being grounded and surrounding the substrate support,
wherein the first member and the second member are individual members and separable from each other.

### E13

The inner chamber assembly according to E12, wherein the first member includes:
one of Si, SiC, SiO₂, or Si₃N₄; and
an aluminum oxide film or a yttrium oxide film.

### E14

The inner chamber assembly according to E13, further comprising: a third member, wherein
the third member is annular and extends along an inner surface of a side portion of the second member.

### E15

The inner chamber assembly according to E14, wherein the third member is substantially L-shape in a cross-sectional view and further extends along a bottom portion of the second member.

### E16

The inner chamber assembly according to E12, wherein the first member includes a protruding edge engaging with an inner peripheral edge of the second member to enable the separability.

### E17

The inner chamber assembly according to E12, wherein the second member includes a step supporting the first member.

### E18

A substrate processing device, comprising:
a first chamber including a substrate support to receive a substrate; and
a second chamber located in the first chamber, the second chamber including:
a shower head including a movable unit, the movable unit including:
a first member including a ceiling located above the substrate support, and
a second member including a side wall and supporting the first member, the second member being electrically connected to a ground member being grounded and surrounding the substrate support,
wherein the first member and the second member are individual members and separable from each other, and
the shower head supplies a gas to a processing space.

### E19

The substrate processing device according to E18, wherein the first member includes a protruding edge engaging with an inner peripheral edge of the second member to enable the separability.

### E20

The substrate processing device according to E18, further comprising: a third member, wherein
the third member is annular and extends along an inner surface of a side portion of the second member.

### REFERENCE SIGNS LIST

1 Substrate processing device
10 First chamber
20 Second chamber (inner chamber assembly)
21 First member
22 Second member
30 Substrate support
38 Conductor (ground member)
W Substrate

1. A substrate processing device, comprising:
a first chamber including a substrate support to receive a substrate; and
a second chamber located in the first chamber, the second chamber including:
a first member including a ceiling located above the substrate support, and
a second member including a side wall and supporting the first member, the second member being electrically connected to a ground member being grounded and surrounding the substrate support,
wherein the first member and the second member are individual members and separable from each other.

2. The substrate processing device according to claim 1, wherein
the first member and the second member comprise different materials.

3. The substrate processing device according to claim 2, wherein
the first member comprises a Si-containing material.

4. The substrate processing device according to claim 3, wherein
the first member comprises one of Si, SiC, SiO₂, or Si₃N₄, and
the second member comprises a metal material.

5. The substrate processing device according to claim 1, wherein
the first member has a gas hole.

6. The substrate processing device according to claim 1, wherein
the first member includes a protruding edge engaged with the second member.

7. The substrate processing device according to claim 1, further comprising:
a third member located along an inner surface of the side wall in the second member.

8. The substrate processing device according to claim 7, wherein
the third member is annular.

9. The substrate processing device according to claim 8, wherein
the third member includes a plurality of parts separable from each other in a circumferential direction.

10. The substrate processing device according to claim 7, wherein
the third member includes a plurality of parts separable from each other in a vertical direction.

11. The substrate processing device according to claim 7, wherein
the ceiling included in the first member is circular and has a diameter larger than an inner diameter of an upper end of the third member.

12. An inner chamber assembly installable in a chamber in a substrate processing device, the inner chamber assembly comprising:
a first member including a ceiling located above a substrate support to receive a substrate; and
a second member including a side wall and supporting the first member, the second member being electrically connected to a ground member being grounded and surrounding the substrate support,
wherein the first member and the second member are individual members and separable from each other.

13. The inner chamber assembly according to claim 12, wherein the first member includes:
one of Si, SiC, SiO2, or Si₃N₄; and
an aluminum oxide film or a yttrium oxide film.

14. The inner chamber assembly according to claim 13, further comprising: a third member, wherein
the third member is annular and extends along an inner surface of a side portion of the second member.

15. The inner chamber assembly according to claim 14, wherein the third member is substantially L-shape in a cross-sectional view and further extends along a bottom portion of the second member.

16. The inner chamber assembly according to claim 12, wherein the first member includes a protruding edge engaging with an inner peripheral edge of the second member to enable the separability.

17. The inner chamber assembly according to claim 12, wherein the second member includes a step supporting the first member.

18. A substrate processing device, comprising:
a first chamber including a substrate support to receive a substrate; and
a second chamber located in the first chamber, the second chamber including:
a shower head including a movable unit, the movable unit including:
a first member including a ceiling located above the substrate support, the ceiling defining a processing space, and
a second member including a side wall and supporting the first member, the second member being electrically connected to a ground member being grounded and surrounding the substrate support,
wherein the first member and the second member are individual members and separable from each other, and
the shower head supplies a gas to the processing space.

19. The substrate processing device according to claim 18, wherein the first member includes a protruding edge engaging with an inner peripheral edge of the second member to enable the separability.

20. The substrate processing device according to claim 18, further comprising: a third member, wherein
the third member is annular and extends along an inner surface of a side portion of the second member.
